(19) United States
(12) Patent Application Publication
(10) Pub. No.: US 2002/0111014 A1
(43) Pub. Date: Aug. 15, 2002

(54) Planarization method of inter-layer dielectrics and inter-metal dielectrics

(76) Inventors: Pei Reng Jeng, Hsinchu (TW); Shu Li Wu, Nan Tou City (TW); Wan Yi Liu, Kaohsiung (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 09/781,283

(22) Filed: Feb. 13, 2001

(51) Int. Cl. H01L 21/4763; H01L 21/302; H01L 21/461

(52) U.S. Cl. 438/631; 438/624; 438/626; 438/633

(57) ABSTRACT

The present invention discloses a planarization method of inter-layer dielectrics (ILD) and inter-metal dielectrics (IMD). The key point of the present invention is that after the planarization process of the ILD and the IMD is performed by means of the chemical mechanical polishing (CMP), a cap layer is formed thereon. The cap layer can be a silicon nitride layer, a silicon nitrogen-oxide layer, or a silicon rich oxide layer having a refractive index not less than 1.6. The cap layer can be transmitted by UV light. The effects of the cap layer are to fill micro scratches generated by the CMP and to enhance the functions of anti-reflection and preventing the diffusion of hydrogen atoms. Thereby, the tolerance of subsequent exposition process can be increased. Moreover, the capabilities of data retention of device and device passivation can be enhanced.

### FIELD OF THE INVENTION

The present invention relates to a planarization method of inter-layer dielectrics (ILD) and inter-metal dielectrics (IMD) in integrated circuits (ICs) and, more particularly, to a method, which is used for enhancing the capability of filling micro scratches generated by the chemical mechanical polishing (CMP) and has the functions of anti-reflection and preventing the diffusion of hydrogen atoms.

### BACKGROUND OF THE INVENTION

Recently, due to the growth of integration of ICs, the miniaturized interconnects of ICs have developed from previous simple structures of two or three layers to multilevel interconnects of more than four layers. Therefore, the planarity of each layer in an IC directly influences the difficulty of manufacturing a multi-layer stacked architecture, and thus becomes one important factor of consideration in modern semiconductor fabrication processes.

The CMP is a commonly used technique nowadays for global planarization of ILD or IMD. The CMP makes use of mechanical polishing matched with proper slurry to lap the surfaces of ILD or IMD. The CMP can provide a planarity larger than 94% for the polished surface.

The dielectric material of ILD extensively used in the semiconductor industry nowadays is borophosphosilicate glass (BPSG) deposited by means of the chemical vapor deposition (CVD). The BPSG is lapped by means of the CMP. Next, a cap layer is formed on the surface of the BPSG. Usually, the cap layer is composed of oxide deposited by means of the plasma enhanced CVD (PECVD) (briefly termed PEOX), or tetraethyl-orthosilicate (TEOS) deposited by means of the PECVD (briefly termed PETEOS), or silicon rich oxide. Additionally, the dielectric of IMD is generally a deposited silicon oxide layer. A PETEOS layer is then formed thereon. Next, the PETEOS is lapped by means of the CMP. A cap layer is then formed on the surface of the PETEOS. The cap layer is composed of TEOS deposited by means of the PECVD. Although the above cap layer on the surface of ILD or IMD can effectively fill micro scratches generated by the CMP, it cannot effectively prevent the diffusion of moisture or hydrogen atoms. Moreover, because the above cap layer has a higher refractive index, bad influences on subsequent exposition process and the capability of data retention of device will be generated.

Accordingly, to resolve the above problems in the prior art, the present invention provides a method, which is used for enhancing the capability of filling micro scratches generated by the CMP and has the functions of antireflection and preventing the diffusion of hydrogen atoms.

### SUMMARY OF THE INVENTION

The primary object of the present invention is to provide a planarization method of ILD and IMD in ICs. Material of high refractive index is exploited to replace the conventional cap layer of dielectric so as to fill micro scratches generated by the CMP, prevent the diffusion of hydrogen atoms, have the function of anti-reflection, increase the tolerance of subsequent exposition process, and enhance the capability of data retention of device. Moreover, the material of high refractive index can be transmitted by ultraviolet (UV) light so that the erasing process of UV light will not be influenced.

The present invention exploits the following steps to achieve the above object. First, a semiconductor substrate already completing front fabrication procedures is provided. The substrate comprises sources, drains, gates, and field oxides (FOX). A dielectric layer is formed on the substrate by means of the CVD. The dielectric layer is then lapped by means of the CMP. Next, a cap layer of high refractive index is formed on the dielectric layer.

The present invention can also exploit the following steps to achieve the above object. First, a semiconductor substrate already completing front fabrication procedures is provided. A metallic layer is formed on the substrate. Next, a dielectric layer is formed on the metallic layer. The dielectric layer is then lapped by means of the CMP. Finally, a cap layer of high refractive index is formed on the dielectric layer.

The various objects and advantages of the present invention will be more readily understood from the following detailed description when read in conjunction with the appended drawings, in which:

### BRIEF DESCRIPTION OF THE DRAWINGS

FIGS. 1A to 1D are cross-sectional views showing the planarization flowchart of ILD according to an embodiment of the present invention; and

FIGS. 2A to 2D are cross-sectional views showing the planarization flowchart of IMD according to another embodiment of the present invention.

### DETAILED DESCRIPTION OF THE PREFERRED EMBODIMENTS

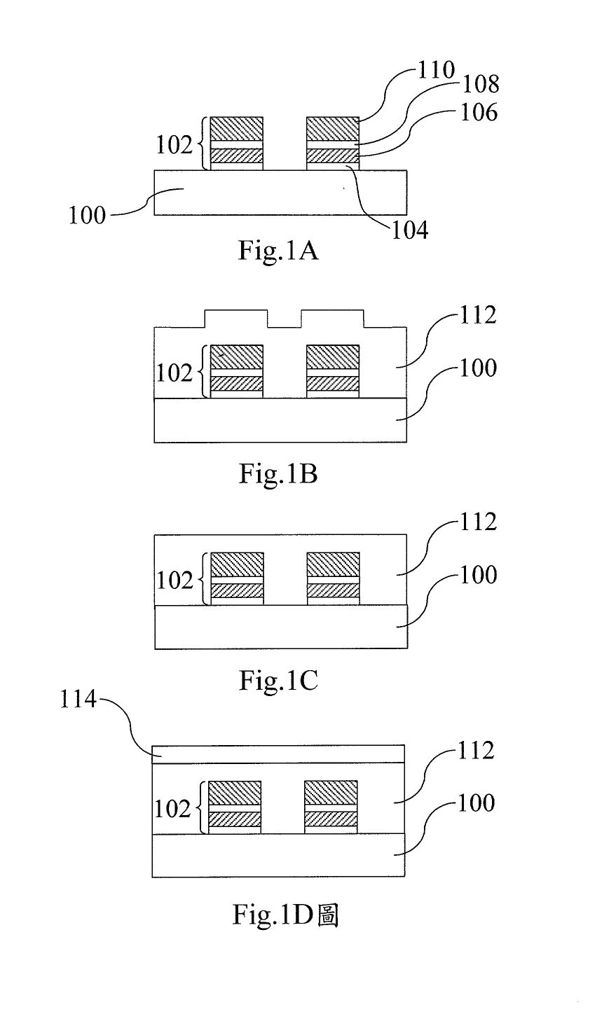

FIGS. 1A to 1C are cross-sectional views showing the planarization flowchart of ILD according to a preferred embodiment of the present invention. These figures only show the key steps in the fabrication process.

As shown in FIG. 1A, a semiconductor substrate 100 is provided. Devices (not shown) such as field oxides, sources, and drains have been formed on the semiconductor substrate 100. A stacked type gate 102 is formed on the surface of the semiconductor substrate 100. The gate 102 at least comprises a tunneling oxide layer 104, a floating gate 106, a dielectric layer 108, and a control gate 110. The floating gate 106 and the control gate 110 are composed of polysilicon. The dielectric layer 108 is usually an oxide layer, and can also comprise an oxide layer, a nitride layer (usually silicon nitride), and an oxide layer (an oxide-nitride-oxide film, briefly termed an ONO film). The tunneling oxide layer 104 and the dielectric layer 108 are generally formed by depositing oxide and then covering the poly-silicon with the oxide by means of the CVD.

As shown in FIG. 1B, a BPSG layer 112 used as an ILD is deposited on the exposed surfaces of the gate 102 and the semiconductor substrate 100 by means of the CVD. Usually, the thickness of the BPSG layer 112 is between 3000˜15000 angstroms, and is preferably between 8000˜13000 angstroms. The CVD can be the atmospheric pressure CVD (APCVD), the plasma enhanced CVD (PECVD), or the sub-atmospheric CVD (SACVD). The operational temperature is about between 400˜500 degrees of centigrade. The pressure is between the atmospheric pressure and 10 torrs.

Next, as shown in FIG. 1C, the CMP is adopted to lap the BPSG layer 112 to meet the requirement of global planarization.

Finally, as shown in FIG. 1D, a cap layer 114 of high refractive index dielectric is formed on the lapped BPSG layer 112. The thickness of the cap layer 114 is generally between 300˜2000 angstroms, and is preferably between 500˜1200 angstroms. The cap layer 114 can be a silicon nitride layer, a silicon nitrogen-oxide layer, or a silicon rich oxide layer having a refractive index (RI) not less than 1.6 (RI≧1.6). The cap layer can be transmitted by UV light. Therefore, the dielectric of the above cap layer 114 can be a dielectric having an RI not less than 1.6 (RI≧1.6). Its object is to enhance the gap-filling capability so that micro scratches generated on the surface of the BPSG layer 112 by the CMP can be completely filled. Its another object is to enhance the capabilities of preventing the diffusion of hydrogen atoms and blocking impurities. Because the RI of the dielectric of the cap layer 114 is larger than that of the dielectric of the prior art cap layer, and the thickness and the RI of the dielectric of the cap layer 114 can be adjusted, the cap layer has the function of anti-reflection. The above cap layer 114 can also increase the degree of global planarization of ILD. Moreover, because its RI is large, the function of anti-reflection is enhanced so as to increase the tolerance and accuracy of subsequent exposition process.

Additionally, because the dielectric of the cap layer 114 of the present invention can be transmitted by UV light, the erasing process of UV light will not be influenced so that the capabilities of data retention of flash memory and device passivation can be enhanced.

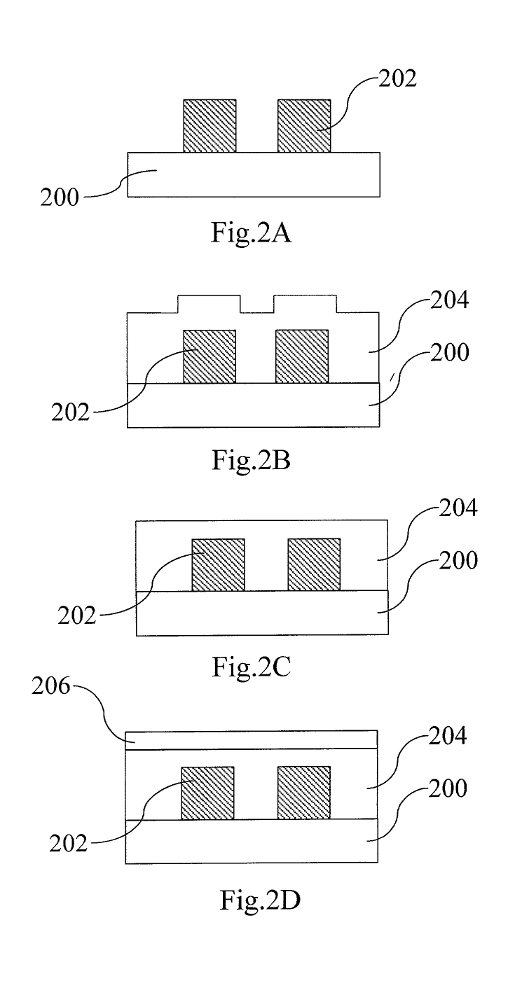

FIGS. 2A to 2D are cross-sectional views showing the planarization flowchart of IMD according to another embodiment of the present invention. As shown in FIG. 2A, a semiconductor substrate 200 already completing front fabrication procedures is provided. A plurality of metal-interconnects 202 are formed on the surface of the semiconductor substrate 200. The metal-interconnect 202 can be composed of aluminum (Al), aluminum-copper (Al—Cu) alloy, aluminum-silicon-copper (Al—Si—Cu) alloy, or copper (Cu).

As shown in FIG. 2B, a dielectric layer 204 used as an IMD is formed on the surfaces of the metal-interconnects 202 and the substrate 200. The above dielectric layer 204 is generally composed of phosphosilicate glass (PSG), fluorosilicate glass (FSG), low dielectric constant (K) dielectric, silicon oxide formed by means of the PECVD, or TEOS formed by means of the PECVD.

Next, as shown in FIG. 2C, the dielectric layer 204 is lapped by means of the CMP to meet the requirement of global planarization.

Finally, as shown in FIG. 2D, a cap layer 206 of dielectric of high refractive index and high extinction coefficient is formed on the lapped dielectric layer 204. The cap layer 206 can be a silicon nitride layer, a silicon nitrogen-oxide layer, or a silicon rich oxide layer having an RI not less than 1.6 (RI≧1.6). The cap layer can be transmitted by UV light. Therefore, the dielectric of the above cap layer 206 can be a dielectric having an RI not less than 1.6 (RI≧1.6). Its object is to enhance the gap-filling capability so that micro scratches generated on the surface of the dielectric layer 204 by the CMP can be completely filled. Its another object is to enhance the capabilities of preventing the diffusion of hydrogen atoms and blocking impurities. The above cap layer having a high RI can effectively increase the degree of global planarization of IMD. Moreover, because its RI is large, the function of anti-reflection is enhanced so as to increase the tolerance and accuracy of subsequent exposition process. Its other effects are commensurate to those of the above ILD and thus will not be further described.

Although the present invention has been described with reference to the preferred embodiments thereof, it will be understood that the invention is not limited to the details thereof. Various substitutions and modifications have been suggested in the foregoing description, and other will occur to those of ordinary skill in the art. Therefore, all such substitutions and modifications are intended to be embraced within the scope of the invention as defined in the appended claims.

I claim:

1. A planarization method of inter-layer dielectrics, comprising the steps of:
providing a semiconductor substrate already completing the basic process of forming devices such as a field oxide, a source, a drain, and a gate thereon;
forming a dielectric layer used as an inter-layer dielectric on said semiconductor substrate, lapping said dielectric layer by means of the chemical mechanical polishing; and
forming a cap layer of high refractive index on said lapped dielectric layer.

2. The planarization method of inter-layer dielectrics as claimed in claim 1,
wherein said gate comprises from bottom to top a tunneling oxide layer, a floating gate, a dielectric layer, and a control gate.

3. The planarization method of inter-layer dielectrics as claimed in claim 2,
wherein said floating gate and said control gate are composed of polysilicon.

4. The planarization method of inter-layer dielectrics as claimed in claim 1,
wherein said dielectric layer is a borophosphosilicate glass layer.

5. The planarization method of inter-layer dielectrics as claimed in claim 1,
wherein said cap layer is a silicon nitride layer capable of being transmitted by ultra-violet light.

6. The planarization method of inter-layer dielectrics as claimed in claim 1,
wherein said cap layer is a silicon nitrogen-oxide layer.

7. The planarization method of inter-layer dielectrics as claimed in claim 1,
wherein said cap layer is a silicon rich oxide layer having a refractive index not less than 1.6.

8. The planarization method of inter-layer dielectrics as claimed in claim 1,
wherein said cap layer is a dielectric layer having a refractive index not less than 1.6.

9. A planarization method of inter-metal dielectrics, comprising the steps of:
providing a semiconductor substrate having a plurality of metal-interconnects formed thereon;
forming a dielectric layer used as an inter-metal dielectric on said substrate, lapping said dielectric layer by means of the chemical mechanical polishing; and
forming a cap layer of high refractive index on said lapped dielectric layer.

10. The planarization method of inter-metal dielectrics as claimed in claim 9,
wherein said metal-interconnect is composed of aluminum, aluminum-copper alloy, aluminum-silicon-copper alloy, or copper.

11. The planarization method of inter-metal dielectrics as claimed in claim 9,
wherein said dielectric layer is a phosphosilicate glass layer.

12. The planarization method of inter-metal dielectrics as claimed in claim 9,
wherein said dielectric layer is a fluorosilicate glass layer.

13. The planarization method of inter-metal dielectrics as claimed in claim 9,
wherein said dielectric layer is a low K dielectric layer.

14. The planarization method of inter-metal dielectrics as claimed in claim 9,
wherein said dielectric layer is a silicon oxide layer formed by means of the plasma enhanced chemical vapor deposition.

15. The planarization method of inter-metal dielectrics as claimed in claim 9,
wherein said dielectric layer is a tetraethyl-orthosilicate layer formed by means of the plasma enhanced chemical vapor deposition.

16. The planarization method of inter-metal dielectrics as claimed in claim 9,
wherein said cap layer is a silicon nitride layer capable of being transmitted by ultra-violet light.

17. The planarization method of inter-metal dielectrics as claimed in claim 9,
wherein said cap layer is a silicon nitrogen-oxide layer.

18. The planarization method of inter-metal dielectrics as claimed in claim 9,
wherein said cap layer is a silicon rich oxide layer having a refractive index not less than 1.6.

19. The planarization method of inter-metal dielectrics as claimed in claim 9,
wherein said cap layer is a dielectric layer having a refractive index not less than 1.6.
